(19) United States
(12) Patent Application Publication
(10) Pub. No.: US 2015/0214239 A1
(43) Pub. Date: Jul. 30, 2015

(54) THREE DIMENSIONAL NON-VOLATILE MEMORY WITH CHARGE STORAGE NODE ISOLATION

(71) Applicant: CONVERSANT INTELLECTUAL PROPERTY MANAGEMENT INC., Ottawa (CA)

(72) Inventor: Hyoung Seub RHIE, Ottawa (CA)

(21) Appl. No.: 14/556,498

(22) Filed: Dec. 1, 2014

Related U.S. Application Data
(60) Provisional application No. 61/912,273, filed on Dec. 5, 2013.

(51) Int. Cl. H01L 27/115; H01L 29/66

(52) U.S. Cl. CPC H01L 27/11556; H01L 27/11565; H01L 29/66666; H01L 29/66825

(57) ABSTRACT

A three-dimensional integrated circuit nonvolatile memory array includes a memory array with a plurality of string stacks laterally disposed in parallel over a substrate to intersect with a plurality of parallel conductive gate structures separated from one another by intervening fin-shaped dielectric structures, where each string stack includes conductive strips separated from each other by interlayer insulating strips, and where a charge storage node is positioned between each conductive strip and each intersecting conductive gate structure to be electrically isolated from neighboring charge storage nodes x, y, and z directions.

### CROSS-REFERENCE TO RELATED APPLICATION

This application claims the benefit under 35 U.S.C. §119(e) of U.S. Provisional Application No. 61/912,273, filed Dec. 5, 2013, entitled “A Three Dimensional Non-Volatile Memory with Charge Storage Node Isolation”, which is hereby incorporated by reference.

### BACKGROUND OF THE INVENTION

1. Field of the Invention

The present invention is directed in general to integrated circuit devices and methods for manufacturing same. In one aspect, the present invention relates to nonvolatile memory devices, such as NAND flash memory and other types of flash memory.

2. Description of the Related Art

With the increasing demand for nonvolatile data storage in consumer electronics having mass storage, such as video or audio players, digital cameras, and other computerized devices, there continues to be interest in having nonvolatile memory devices progress over time towards having smaller sizes, larger memory capacity, and improved performance. Flash memory is a commonly used type of nonvolatile memory which can take the form of memory cards or USB type memory sticks, each having at least one memory device and a memory controller formed therein. For example, the need to reduce manufacturing costs per data bit is driving the NAND flash industry to continuously reduce the size of the cell transistors. But as fabrication process limitations (for example, limitations imposed by photolithography tools) limit the ability to reduce physical transistor sizes, there have been structural and/or design schemes proposed to increase memory density, such as, for example, stacking NAND cells in a direction perpendicular to the chip surface, thereby reducing the effective chip area per data bit without requiring shrinkage of the physical cell transistor size. However, there continue to be challenges associated with designing, fabricating, and operating vertical NAND flash memory devices.

### BRIEF DESCRIPTION OF THE DRAWINGS

The present invention may be understood, and its numerous objects, features and advantages obtained, when the following detailed description is considered in conjunction with the following drawings, in which:

FIG. 1 illustrates a simplified cross-sectional schematic representation of a vertically stacked array of vertical channel NAND flash cell strings formed over a substrate;

FIG. 2 illustrates a simplified cross-sectional schematic representation of a vertically stacked array of vertical gate NAND flash cell strings formed over a substrate;

FIG. 3 illustrates a simplified schematic diagram of a three-dimensional vertical gate NAND flash memory array using charge trap technology for the stacked strings;

FIG. 4 illustrates a partial cross section view of a vertical gate NAND flash string stack with a continuous charge trap layer;

FIG. 5 illustrates a simplified perspective view of a three-dimensional vertical gate NAND flash memory array architecture using isolated floating gate NAND Flash cells for the stacked strings;

FIG. 6 illustrates a simplified cross-sectional view of a vertical gate NAND flash memory structure with isolated floating gate NAND cells at a word line location;

FIG. 7 illustrates a simplified cross-sectional view of the vertical gate NAND flash memory structure depicted in FIG. 6 at a dielectric fin location between word lines;

FIG. 8 illustrates a simplified plan view of the vertical gate NAND flash memory structure depicted in FIG. 6 at a cut line through a layer of isolated floating gate NAND cells;

FIG. 9 illustrates a simplified plan view of the vertical gate NAND flash memory structure depicted in FIG. 6 at a cut line between vertically stacked strings;

FIG. 10 illustrates selected partial cross-section and plan views of the vertical gate NAND flash memory structure during an initial step in an example fabrication sequence when a memory stack is formed;

FIG. 10a illustrates a 1^{st} selected partial cross-section and plan view of the vertical gate NAND flash memory structure during an initial step in an example fabrication sequence when a memory stack is formed;

FIG. 10b illustrates a 2^{nd} selected partial cross-section and plan view of the vertical gate NAND flash memory structure during an initial step in an example fabrication sequence when a memory stack is formed;

FIG. 10c illustrates a 3^{rd} selected partial cross-section and plan view of the vertical gate NAND flash memory structure during an initial step in an example fabrication sequence when a memory stack is formed;

FIG. 10d illustrates a 4^{th} selected partial cross-section and plan view of the vertical gate NAND flash memory structure during an initial step in an example fabrication sequence when a memory stack is formed;

FIG. 11 illustrates processing subsequent to FIG. 10 after the memory stack is patterned and etched to form stacked strings;

FIG. 11a illustrates processing subsequent to the corresponding FIG. 10 after the memory stack is patterned and etched to form stacked strings;

FIG. 11b illustrates processing subsequent to the corresponding FIG. 10 after the memory stack is patterned and etched to form stacked strings;

FIG. 11c illustrates processing subsequent to the corresponding FIG. 10 after the memory stack is patterned and etched to form stacked strings;

FIG. 11d illustrates processing subsequent to the corresponding FIG. 10 after the memory stack is patterned and etched to form stacked strings;

FIG. 12 illustrates processing subsequent to FIG. 11 after recess etching of the stacked strings;

FIG. 12a illustrates processing subsequent to the corresponding FIG. 11 after recess etching of the stacked strings;

FIG. 12b illustrates processing subsequent to the corresponding FIG. 11 after recess etching of the stacked strings;

FIG. 12c illustrates processing subsequent to the corresponding FIG. 11 after recess etching of the stacked strings;

FIG. 12d illustrates processing subsequent to the corresponding FIG. 11 after recess etching of the stacked strings;

FIG. 13 illustrates processing subsequent to FIG. 12 after a tunnel dielectric layer is formed to cover the stacked strings;

FIG. 13a illustrates processing subsequent to the corresponding FIG. 12 after a tunnel dielectric layer is formed to cover the stacked strings;

FIG. 13b illustrates processing subsequent to the corresponding FIG. 12 after a tunnel dielectric layer is formed to cover the stacked strings;

FIG. 13c illustrates processing subsequent to the corresponding FIG. 12 after a tunnel dielectric layer is formed to cover the stacked strings;

FIG. 13d illustrates processing subsequent to the corresponding FIG. 12 after a tunnel dielectric layer is formed to cover the stacked strings;

FIG. 14 illustrates processing subsequent to FIG. 13 after forming patterned fin-shaped dielectric layers between stacked strings;

FIG. 14a illustrates processing subsequent to the corresponding FIG. 13 after forming patterned fin-shaped dielectric layers between stacked strings;

FIG. 14b illustrates processing subsequent to the corresponding FIG. 13 after forming patterned fin-shaped dielectric layers between stacked strings;

FIG. 14c illustrates processing subsequent to the corresponding FIG. 13 after forming patterned fin-shaped dielectric layers between stacked strings;

FIG. 14d illustrates processing subsequent to the corresponding FIG. 13 after forming patterned fin-shaped dielectric layers between stacked strings;

FIG. 15 illustrates processing subsequent to FIG. 14 after formation of a polysilicon gate layer;

FIG. 15a illustrates processing subsequent to the corresponding FIG. 14 after formation of a polysilicon gate layer;

FIG. 15b illustrates processing subsequent to the corresponding FIG. 14 after formation of a polysilicon gate layer;

FIG. 15c illustrates processing subsequent to the corresponding FIG. 14 after formation of a polysilicon gate layer;

FIG. 15d illustrates processing subsequent to the corresponding FIG. 14 after formation of a polysilicon gate layer;

FIG. 16 illustrates processing subsequent to FIG. 15 after the polysilicon layer is etched to form isolated floating gate nodes;

FIG. 16a illustrates processing subsequent to the corresponding FIG. 15 after the polysilicon layer is etched to form isolated floating gate nodes; and

FIG. 16b illustrates processing subsequent to the corresponding FIG. 15 after the polysilicon layer is etched to form isolated floating gate nodes;

FIG. 16c illustrates processing subsequent to the corresponding FIG. 15 after the polysilicon layer is etched to form isolated floating gate nodes;

FIG. 16d illustrates processing subsequent to the corresponding FIG. 15 after the polysilicon layer is etched to form isolated floating gate nodes;

FIG. 17a illustrates processing subsequent to the corresponding FIG. 16 after a coupling dielectric layer is formed to cover the stacked strings;

FIG. 17b illustrates processing subsequent to the corresponding FIG. 16 after a coupling dielectric layer is formed to cover the stacked strings;

FIG. 17c illustrates processing subsequent to the corresponding FIG. 16 after a coupling dielectric layer is formed to cover the stacked strings; and

FIG. 17 illustrates processing subsequent to FIG. 16 after a coupling dielectric layer is formed to cover the stacked strings;

FIG. 17d illustrates processing subsequent to the corresponding FIG. 16 after a coupling dielectric layer is formed to cover the stacked strings.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

In a three-dimensional vertical gate NAND flash memory device, a stacked memory architecture and cell array structure includes isolated charge trap nodes, such as floating gates or other charge trap devices, formed on opposite sides of stacked NAND strings without extending across multiple word lines to provide electrically isolated charge trap nodes at each cell that are structurally separated from neighboring cells. In selected embodiments, stacked VG NAND devices include self-aligned charge trap devices in each word line that are electrically and structurally isolated from charge trap devices in adjacent word lines by patterned fin-shaped dielectric structures formed between word line gates. To achieve the isolated storage nodes, there is disclosed herein a manufacturable device and fabrication sequence for vertical and lateral charge storage node isolation of VG NAND floating gates or charge trapping devices. In selected example embodiments, the fabrication sequence forms vertically stacked NAND flash strings with self-aligned float gates which are separated from floating gates in laterally adjacent string stacks by one or more patterned dielectric layers formed between laterally adjacent string stacks. As a result, storage node separation is achieved in not only the vertical direction, but also both horizontal (x and y) directions without increasing the processing cost or complexity of having additional photolithographic patterning steps.

In this disclosure, an improved system, apparatus, and fabrication method are described for fabricating vertical gate NAND flash memory devices with charge trap nodes that are electrically isolated from charge trap node in vertically and horizontally adjacent NAND strings to address various problems in the art where various limitations and disadvantages of conventional solutions and technologies will become apparent to one of skill in the art after reviewing the remainder of the present application with reference to the drawings and detailed description provided herein. For example, there are manufacturing challenges with isolating charge storage nodes imposed by the additional costs and complexity of photolithographic patterning used to achieve storage node separation between vertically and horizontally adjacent memory cells. While there have been attempts to isolate charge storage nodes by using charge trap technology, such as Silicon-Oxide-Nitride-Oxide-Silicon (SONOS) gate structures, to trap electrons in dielectric films, any electrical isolation depends solely on the natural insulating nature of the dielectric layer(s) to inhibit charge leakage between adjacent cells, and does not typically require the charge trap layers to be actively patterned into isolated island-shaped patterns where each cell is electrically isolated from all of its neighboring cells. To address these problems and others known to those skilled in the art, various illustrative embodiments of the present invention will now be described in detail with reference to the accompanying figures. While various details are set forth in the following description, it will be appreciated that the present invention may be practiced without these specific details, and that numerous implementation-specific modifications may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified drawings and representations of a flash memory device without including every device feature, geometry, or circuit detail in order to avoid limiting or obscuring the present invention. Such descriptions and representations are used by those skilled in the art to describe and convey the substance of their work to others skilled in the art. In addition, although specific example materials are described herein, those skilled in the art will recognize that other materials with similar properties can be substituted without loss of function. It is also noted that, throughout this detailed description, certain materials will be formed and removed to fabricate the semiconductor structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art how to make or use the present invention.

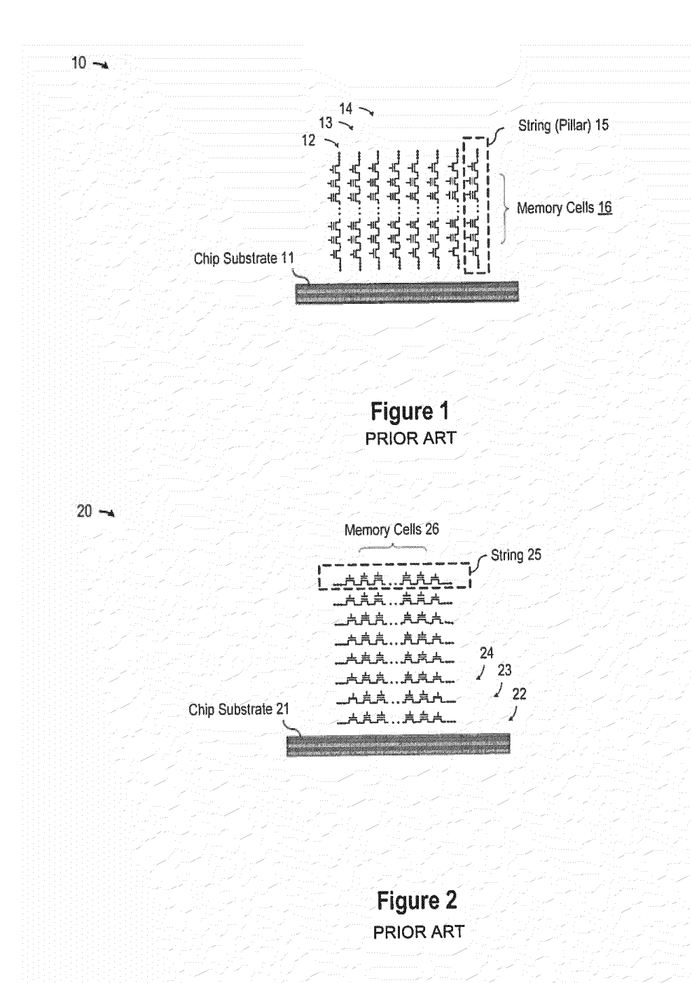

To provide a contextual framework for selected embodiments of the present disclosure, reference is now made to FIGS. 1 and 2 which illustrate different stacking configurations for NAND flash memory devices which are used to reduce manufacturing costs per data bit by reducing the size of the cell transistors while increasing the memory array sizes that would not otherwise be possible in a two-dimensional memory design due to the limitations imposed by photolithography tools and the limits of shrinking the physical transistor size. By stacking NAND cells in a direction perpendicular to the chip surface, the effective chip area per data bit can be reduced without relying on shrinkage of the physical cell transistor size. Generally speaking, there are two main types of stacked NAND flash memory device architectures. First, and as illustrated in simplified cross-sectional schematic form in FIG. 1, a vertically stacked array 10 may be fabricated with vertical channel NAND flash cell strings 12-15 formed over a substrate 11 to run in a direction that is perpendicular or orthogonal to the chip substrate 11. In the vertical channel NAND architecture, the memory cells 16 belonging to the same string are stacked vertically on top of each other, and different strings 12-15 are arranged as pillars that are laterally positioned next to one another. By convention, the device architecture for the vertically stacked array 10 may be referred to as Vertical Channel NAND or VC NAND. Second, and as illustrated in simplified cross-sectional schematic form in FIG. 2, a vertically stacked array 20 may be fabricated with vertical gate NAND flash cell strings 22-25 formed over a substrate 21 to run in a direction that is parallel to the chip substrate 21. In this alternative architecture, memory cells 26 belonging to the same string (for example, 22) are aligned in a direction parallel to the chip surface as in conventional NAND cells, but additional strings (for example, 23-25) are stacked vertically on top of each other. By convention, the device architecture for the vertically stacked array 20 may be referred to as Vertical Gate NAND or VG NAND.

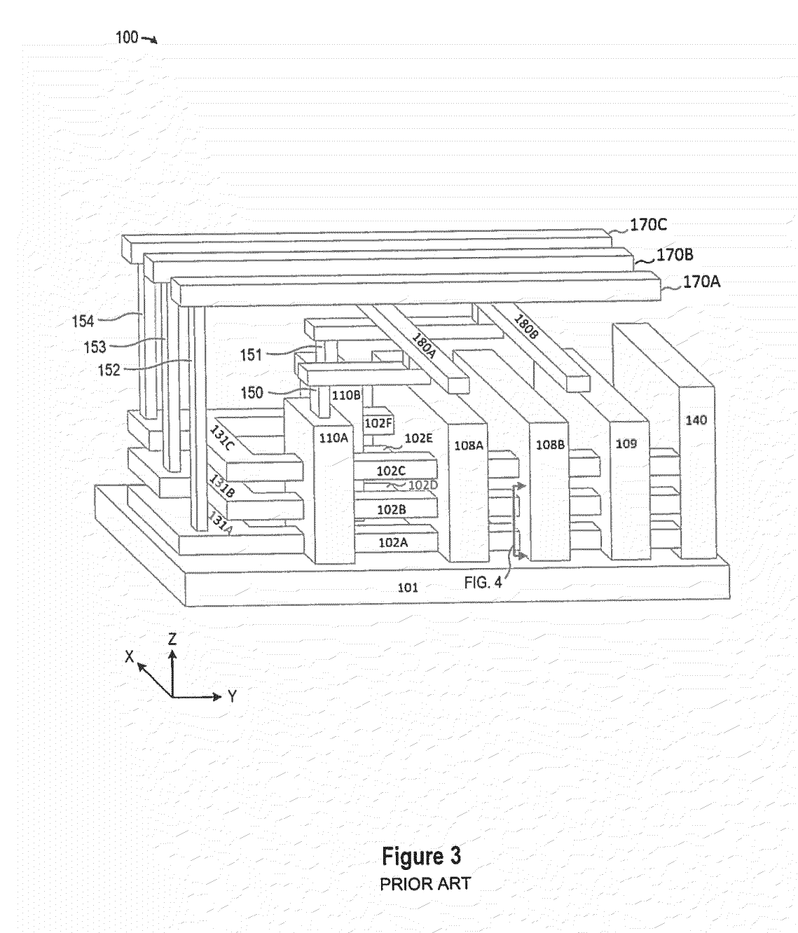

Turning now to FIG. 3, there is shown a three-dimensional array architecture of a vertical gate NAND flash memory 100 using charge trap layers around each stacked string 102A-F. In the VG NAND flash memory 100, a plurality of stacked cell strings 102A-F are formed over a chip substrate 101 to extend through separate word line gate structures 108A, 108B, with each cell string running in a direction (e.g., y direction) that is parallel to the surface of the chip substrate 101. The layout of the VG NAND 100 resembles a conventional NAND memory, but with word lines and bit lines grouped in each plane and with string select transistors connecting each string to a corresponding bit line pad 131A-C. As shown, each NAND string is formed with a silicon strip (for example, patterned poly layer 102A) in which channels are formed to run in a horizontal direction that is parallel to the chip surface, with different NAND strings (for example, patterned poly layers 102B, 102C) stacked on top of each other. In the illustrated example, the cell transistors formed along each silicon strip (for example, 102A-C) are formed as dual gate devices by forming a word line gate structure 108A, 108B with multi-layered memory film structure (not shown) to surround the silicon strip with opposing gates where each cell channel is formed. Though not separately shown, it will be appreciated that each multi-layered memory film structure formed around each string for each memory cell transistor may include a tunnel dielectric layer formed to surround the channel region of the silicon strip, a charge storage layer (for example, ONO) formed around the tunnel dielectric layer, and a coupling dielectric formed around the charge storage layer. Around each multi-layered memory film structure, a word line gate structure 108A, 108B may be formed with one or more patterned polysilicon layers to extend across multiple strings in a word line direction (e.g., x direction). In addition, the transistors formed in each silicon strip may include implanted and/or diffused source/drain regions (for example, n+regions) on at least the string select transistor and ground select transistor, if not also the memory cell transistors. In other embodiments, the memory cell transistors may be formed as junction-free cells with virtual source/drain regions formed to have conductivity that depends on the existence of electric fringe fields between gates adjacent to the source/drain regions and the source/drain silicon itself.

In addition to the separate word line gate structures 108A, 108B defining multiple memory cells, each string also includes additional gate structures on each end of the string to define ground and string select line transistors. As shown, the ground select line transistors may be formed with a poly gate structure 109 which connects the source node of each stacked string 102A-F to a shared or common source line 140, while string select transistors may be formed with separate poly gate structures 110A, 110B, each of which connects the drain nodes of vertically stacked strings 102A-F to a corresponding bit line pad 131A-C under control of a string select signal applied via metal line conductors 180A, 180B and contacts 150, 151. In this way, the source node of each string is shared with adjacent strings that are located above or below it in a vertical direction via a source contact using the common source line 140, but the drain node of each string (e.g., 102C) is shared only horizontally with other strings (e.g., 102F) via a bit line pad (e.g., 131C), but not vertically. If desired, the ground and string select transistors may be formed as dual gate devices substantially as described above. For example, the string select transistor at the drain node of each string may be formed with a poly gate structure (for example, 110A, 110B) formed around a multi-layered memory film structure, while the ground select transistor at the source node of each string may be formed with a poly gate structure 109 formed around a multi-layered memory film structure.

By forming each word line gate structure 108A-B around the multi-layered memory film structures to extend horizontally across separate vertical stacks of silicon strips (for example, 102A-C and 102D-F), separate word line (WLi) signals may be connected to each poly gate node 108A-B of the cell transistors in a horizontal or lateral direction. In addition, each cell transistor shares its poly gate node 108A-B (and applied word line WLi signal) with all cell transistors that are stacked vertically above it. Bit lines can also be shared by one or more strings formed in the same layer (for example, 102A, 102D) by connecting the strings to a shared bit line pad (for example, 131A) which is used to establish electrical connection from the connected strings to the common bit line (for example, 170A) through one or more via contacts or conductors 152. In similar fashion, strings formed in another layer (for example, 102B, 102E) may be connected to a shared bit line pad (for example, 131B) which is electrically connected to a second common bit line (for example, 170B) through one or more via contacts or conductors 153, while strings formed in another layer (for example, 102C, 102F) may be connected to a shared bit line pad (for example, 131C) which is electrically connected to another common bit line (for example, 170C) through one or more via contacts or conductors 154.

Extending across all stacked cell strings 102A-C and 102D-F, the poly gate structure 109 for the shared ground select transistor connects the source nodes of stacked strings 102A-C and 102D-F to the common source line contact 140. In contrast, each poly gate structure 110A, 110B for a given string select transistor does not extend across multiple strings in the same plane, but is instead formed as an island SSL gate (e.g., 110A), so that each string (for example 102A) shares a common SSL gate (for example, 110A) with the vertically stacked strings (for example, 102B, 102C), but not any strings (for example, 102D) in the same plane.

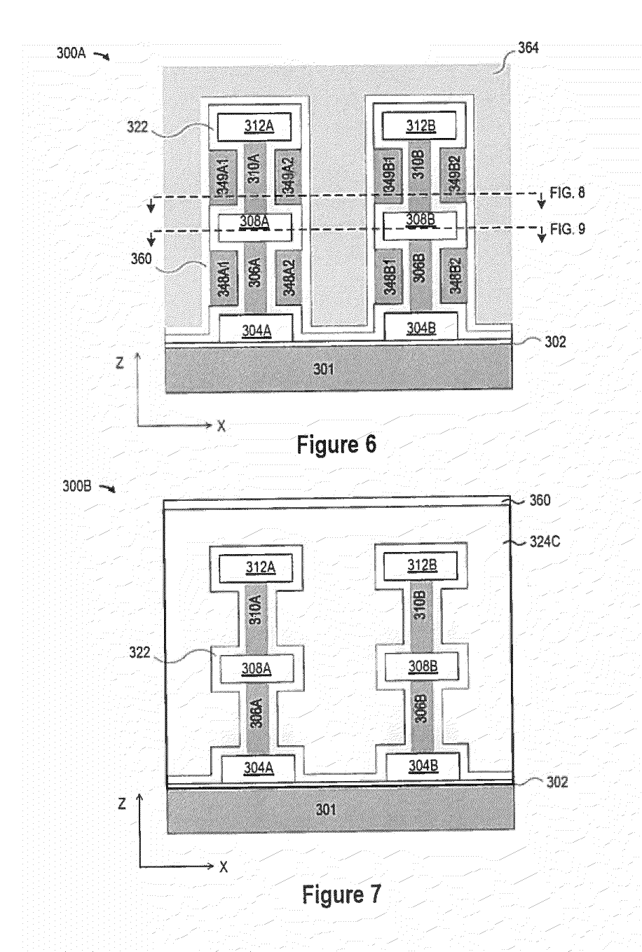

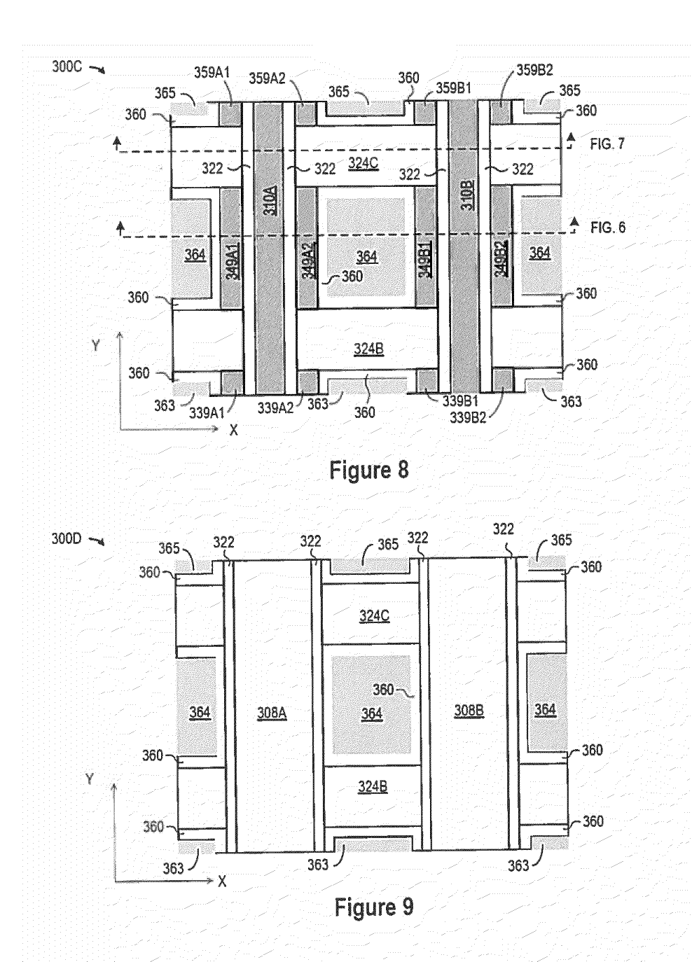

The depicted vertical gate NAND flash memory 100 illustrates selected example embodiments for a three-dimensional array architecture of a vertical gate NAND flash memory which allows individual pages to be selected for read and program operations and which may erase selected blocks in a VG NAND structure. However, it will be appreciated that a vertical gate NAND flash memory may be implemented with different features and structures. For example, the common source line contact 140 may be formed with a different shape or structure, such as a using a plate-shaped layer and/or a conductive line that runs in a horizontal direction and connects vertically to an additional metal line which runs in a horizontal direction. In addition, the arrangement and connection of stacked cell strings 102A-F may be oriented to all run in the same direction, to run alternating strings in opposite directions, or with any desired orientation of different strings. In addition, any desired alignment, shape, and positioning of the island-type string select poly gate structures (for example, 110A, 110B) and/or bit line pads (for example, 131A-C) may be used to establish electrical connection to the metal layers 170A-C through respective via contacts 152-154. It will also be appreciated that the vertical gate NAND flash memory 100 shown in FIG. 6 shows conductive elements, such as interconnections, contacts, string bodies and gate material, to highlight the connectivity of the constituting elements, but does not show isolating materials such as gate dielectrics, interlayer dielectrics, inter-metal dielectrics, etc. Persons skilled in the art will understand that dielectric layers are located around the conductor elements to provide electrical isolation.

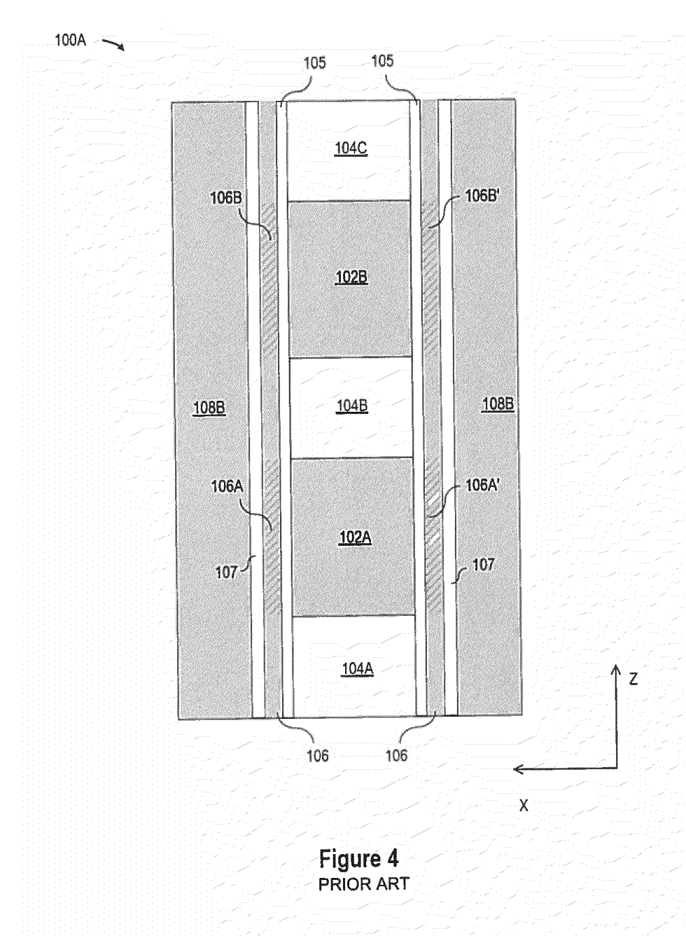

To provide additional details for a better understanding of the multi-layered memory film structure formed around each string, reference is now made to FIG. 4 which illustrates a partial cross section view 100A across the “FIG. 4” cutting plane through the stacked strings 102A, 102B surrounded by the word line 108B shown in FIG. 3. The cross section 100A shows a vertical gate NAND flash string stack 102A, 102B separated from another by alternating dielectric layers 104A-C. In this scheme, cell transistors are formed on the sidewalls of the semiconducting strips 102A/102B. On each side of the string stack, a multi-layered memory film structure 105-107 is formed for each transistor cell, including a tunnel dielectric layer 105 that is formed (for example, deposited or grown) on at least the semiconductor string sidewalls 102A, 102B , a charge storage layer 106 that is formed on the tunnel dielectric 105, and a coupling dielectric 107 (a.k.a., blocking dielectric) that is formed (for example, deposited) on the charge storage layer 106. In addition, the word line material 108B also faces the both sidewalls of each of the two strings. Sandwiched between the tunnel dielectric layer 105 and the coupling dielectric layer 107, the charge storage layer 106 performs a charge trap function by including charge storage nodes or locations 106A/A′, 106B/B′ shown as hatched areas where electrons are trapped. For example, the charge storage nodes 106A/A′, 106B/B′ may be formed as a silicon nitride charge trapping layer within a SONOS (Silicon-Oxide-Nitride-Oxide-Silicon) structure, though other charge storage node structures may be used. By forming the charge storage layer 106 and charge storage nodes 106A/A′, 106B/B′ as a single continuous layer along each string sidewall, the charge storage nodes 106A/A′, 106B/B′ formed with dielectric charge trapping material or with conductive material in each cell are isolated from vertically adjacent cells by dielectric layers. As a result, unintentional charge flow between different cells in the z-direction is inhibited only by the dielectric nature of the charge trap film 106. With three-dimensional vertical gate NAND flash memory array architectures, vertical isolation of the charge trap locations 106A and 106B (which belong to different strings) is not conventionally provided because of process complexity and manufacturing costs. But in some VG NAND devices, the charge trap layers may be patterned laterally in the y-direction to isolate the charge trap films belonging to cells connected to word line 108A and 108B in FIG. 3. For example, charge trap films may be formed on strings (102A-C) between adjacent word line gates (108A or 108B), and then remove the charge trap films with an additional photolithograph etch process at locations which are not covered by word line gates 108A/B. But such additional processing can add substantial processing cost increases.

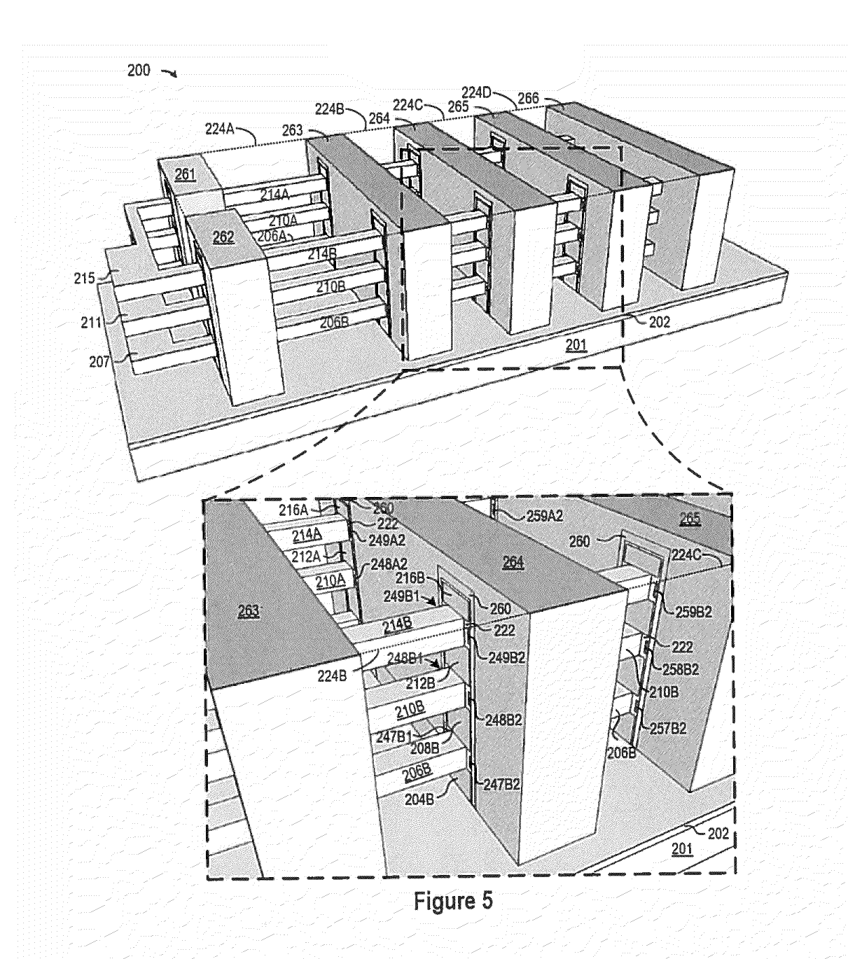

In accordance with selected embodiments disclosed herein, an improved vertical gate NAND flash memory array architecture and associated method of fabrication are disclosed which form isolated charge trap nodes, such as floating gates or other charge trap devices, on opposite sides of stacked NAND strings without extending across multiple word lines to provide electrically isolated charge trap nodes at each cell that are structurally separated from neighboring cells. Selected example embodiments of a vertical gate NAND flash memory cell array are illustrated in FIG. 5 which illustrates a simplified perspective view 200 and close-up view 200A of a three-dimensional vertical gate NAND flash memory array architecture using isolated floating gate NAND Flash cells for the stacked strings. The depicted VG NAND flash memory array 200 is formed over a substrate 201 and protective continuous dielectric film 202, and may include NAND flash strings 206A/B, 210A/B, 214A/B which run horizontally in the y-direction over the substrate 201. Each string includes string select transistors formed with string select gates/lines 261, 262, cell transistors formed with cell control gates 263, 264, and ground select transistors formed with ground select gates 265 which connect the flash strings 206A/B, 210A/B, 214A/B to the common source line 266. In each NAND flash string, the transistors are serially connected with the string select transistor located at one peripheral end, the cell transistors in the middle, and the ground select transistor at opposite peripheral end of the string. In addition, one or more dielectric fill layers or regions 224A-D (indicated with dashed lines) are formed to separate the select gates 261-265 and source line 266.

As shown in the close-up view 200A, each NAND string (e.g., 206B) may be formed with a semiconductor strip which runs in a horizontal direction (e.g., y direction) that is parallel to the chip surface, with additional parallel NAND strings (patterned semiconductor layers 210B, 214B) stacked above and/or below each other to be electrically isolated and separated from one another by alternating dielectric layers 204B, 208B, 212B, 216B. In addition, the cell transistors formed along a vertical stack of strings (e.g., 206B, 210B, 214B) are formed as dual gate devices by forming a word line gate structure (e.g., 264) with multi-layered memory film structure 222, 247-249, 260 to surround at least the sides of the vertical stack of strings with opposing gates where each cell channel is formed. As described more fully hereinbelow, the multi-layered memory film structure formed around a first level string (e.g., 206B) for a memory cell transistor may include a tunnel dielectric layer 222 formed on at least the opposed channel regions of the string, a charge storage layer formed on the tunnel dielectric layer 222 as opposing self-aligned floating gates (e.g., 247B1, 247B2), and a coupling dielectric layer 260 formed around the charge storage layer. In similar fashion, the adjacent vertically stacked string (e.g., 210B) is also surrounded on opposing sides by the tunnel dielectric layer 222, a charge storage layer (e.g., 248B1, 248B2), and coupling dielectric layer 260, while the topmost vertically stacked string (e.g., 214B) is surrounded on opposing sides by the tunnel dielectric layer 222, a charge storage layer (e.g., 249B1, 249B2), and coupling dielectric layer 260. Without belaboring the details, additional cell transistors may be formed along the stacked strings (e.g., 206A/B, 210A/B, 214A/B) by forming one or more additional word line gate structures (e.g., 265) with multi-layered memory film structure 222, 257-259, 260 to surround at least the sides of the vertical stack of strings with opposing gates where each cell channel is formed.

Around each multi-layered memory film structure, a word line gate structure 264 may be formed with one or more patterned polysilicon layers to extend across multiple strings in a word line direction (e.g., x direction). In addition, the transistors formed in each silicon strip may include implanted and/or diffused source/drain regions (for example, n+regions) on at least the string select transistor and ground select transistor, if not also the memory cell transistors. In other embodiments, the memory cell transistors may be formed as junction-free cells with virtual source/drain regions formed to have conductivity that depends on the existence of electric fringe fields between gates adjacent to the source/drain regions and the source/drain silicon itself.

To provide additional details for better understanding selected embodiments of the present disclosure, reference is now made to FIG. 6 which illustrates a simplified cross-sectional view 300A of a vertical gate NAND flash memory structure with isolated floating gate NAND cells at a word line location. In addition, reference is also made to FIG. 7 which illustrates a simplified cross-sectional view 300B of the same vertical gate NAND flash memory structure depicted in FIG. 6 at a dielectric fin location between word lines. While the illustrated cross sections show a pair of two stacked strings, it will be appreciated that any number of string stacks and levels may be used. In each of FIGS. 6-7, the depicted VG NAND flash memory structure includes stacked strings formed with semiconductor strips 306A/B, 310A/B stacked in two vertical layers with lower strings 306A, 396B and upper strings 310A, 310B, although any desired number of string layers may be used. The semiconductor strings are separated from each other, as well as delimited at the bottom (i.e., separated from the silicon substrate 301), and at the top of the string stacks by dielectric strips 304A/B, 308A/B, 312A/B. The delimitation between stacked strings is shown in FIG. 9 which illustrates a simplified plan view 300D of the same vertical gate NAND flash memory structure depicted in FIG. 6 at the “FIG. 9” cut line (shown in FIG. 6) between vertically stacked strings. In addition, a protective continuous dielectric film 302 may be formed on the semiconducting substrate 301 to provide additional electrical isolation. As formed, the semiconductor strips 306A/B, 310A/B are formed with recessed sidewalls which are recessed or offset in a lateral direction (e.g., x-direction) relative to the dielectric strips 304A/B, 308A/B, 312A/B. With the dielectric strips 304A/B, 308A/B, 312A/B protruding in a lateral direction (x-direction) relative to the recessed semiconductor strips 306A/B, 310A/B, a first dielectric film 322 may be formed as a tunnel dielectric that wraps around the stacks consisting of recessed strings 306A/B, 310A/B and dielectric strips 304A/B, 308A/B, 312A/B alike, thereby following the recessed and protruded profiles of the combined string and dielectric stacks to form recessed openings in which isolated floating gates 348A1/A2, 348B1/B2, 349A1/A2, 349B1/B2 are formed along the depicted word line location shown in FIG. 6. However, the isolated floating gates are electrically isolated from horizontally adjacent floating gate structures formed along the y-axis at other word line locations, as shown in FIG. 7 where it can be seen that the recessed and protruded profiles of the combined string and dielectric stack are filled with one or more dielectric layers 324C.

To provide a better understanding of the structure of the isolated floating gates, reference is now made to FIG. 8 which illustrates a simplified plan view 300C of the same vertical gate NAND flash memory structure across the “FIG. 8” cut line (shown in FIG. 6) where the floating gates are located. Conversely, the vertical cross-sectional view of FIG. 6 is taken across the “FIG. 6” cut line shown in FIG. 8, while the vertical cross-sectional view of FIG. 7 is taken across the “FIG. 7” cut line (shown in FIG. 8) where there are no floating gates located. In the embodiments shown in FIGS. 6 and 8, the floating gates 348A1/A2, 348B1/B2, 349A1/A2, 349B1/B2 may be formed with a suitable conductive material, such as polysilicon. Formed in the recessed and protruded profiles of the combined string and dielectric stacks, each floating gate is located adjacent to each of the opposing sidewalls of each string, but separate therefrom by the tunnel dielectric layer 322. In addition, each floating gate is delimited in both vertical directions by the dielectric strips 304A/B, 308A/B, 312A/B and the tunnel dielectric 322. Each floating gate is also delimited in a first lateral direction (e.g., both positive and negative y-direction) by a dielectric fin pattern (e.g., 324B, 324C), as shown in FIGS. 8-9.

Formed around the combined string and dielectric stacks and covering the recessed floating gates is a second dielectric film 360 which acts as a coupling dielectric. As shown in FIG. 6, the coupling dielectric layer 360 wraps around the string stacks at locations where there exist floating gates. However and as shown in FIG. 7, the coupling dielectric layer 360 does not wrap around string stacks at locations where the string stacks are covered by the dielectric fin patterns 324C, but instead covers the dielectric fin patterns 324C. In this way, the coupling dielectric layer 360 delimits each floating gate in a second lateral direction (e.g., x-direction).

The structure of the word lines (e.g., 363-365) and inter-word line dielectric fin patterns (e.g., 324B-C) may each be formed as elongated narrow fin-type structures running in the x-direction to wrap around the string stacks. As shown in FIGS. 6-9, the word lines 363-365 and dielectric fins 324B-C are located alternatingly at different y-coordinates, where the word lines (e.g., 364) wrap around string stacks at y-coordinates where there exist floating gates (e.g., 348A1/A2, 348B1/B2, 349A1/A2, 349B1/B2) covered by the coupling dielectric layer 322, and where the dielectric fins (e.g., 324C) wrap around string stacks at y-coordinates where there do not exist any floating gates.

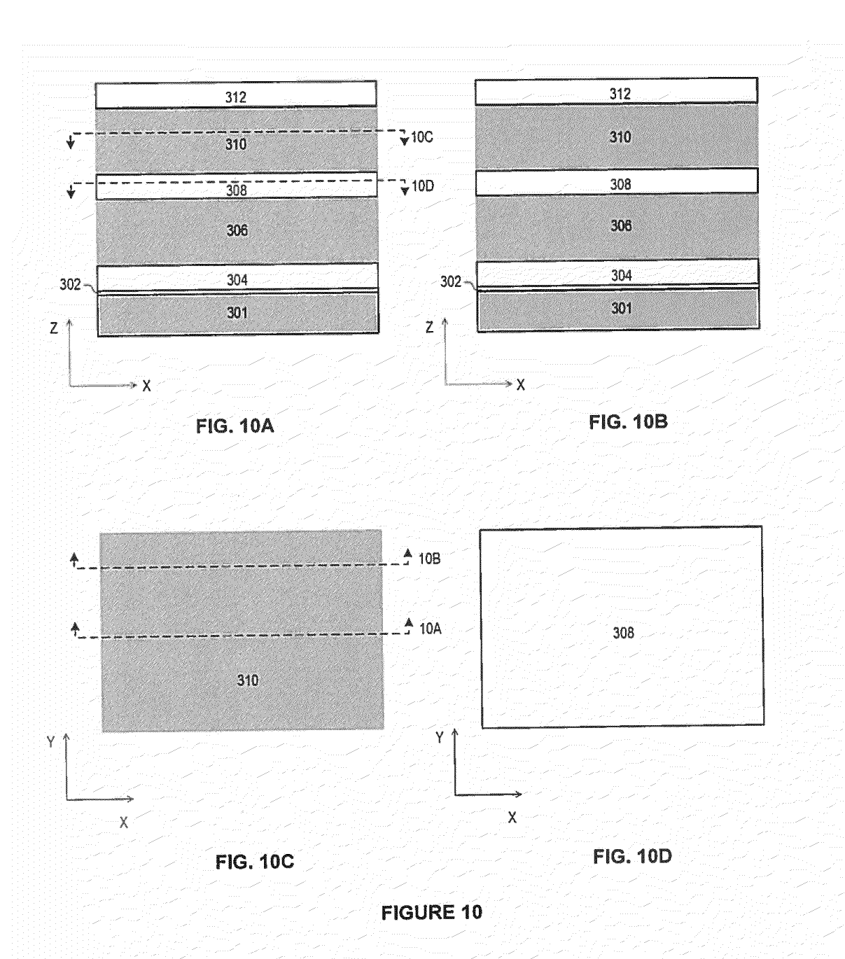

To provide a more detailed understanding of selected embodiments of the present disclosure, reference is now made to FIGS. 10-17 which show cross-section and plan views of a vertical gate NAND flash memory structure having the isolated floating gates during successive phases of a fabrication sequence. Starting first with FIG. 10, there are shown partial cross section views of a memory stack at a word line location (FIG. 10A) and an adjacent dielectric fin location (FIG. 10B), along with partial plan views of the memory stack through a string layer location (FIG. 10C) and adjacent isolation layer between string layers (FIG. 10D). In the cross sectional views of FIGS. 10A-B, a memory stack is formed over a substrate 301 and protective dielectric layer 302 with a plurality of semiconductor layers 306, 310 and isolating dielectric layers 304, 308, 312 alternately formed over the substrate 301. The substrate 301 may be formed with an appropriate semiconductor material (for example, monocrystalline or polycrystalline silicon), such as a bulk semiconductor substrate, semiconductor-on-insulator (SOI) substrate, or a polysilicon layer. On the substrate, the protective dielectric layer 302 may be formed by depositing or growing a continuous dielectric film, such as silicon dioxide or silicon nitride. The memory stack may be formed by growing or depositing alternating layers of insulating dielectric material (e.g., silicon oxide) and semiconductor material (e.g., polysilicon) over the wafer substrate 301. For example, on the bottom-most protective dielectric layer 302, a first insulating layer 304 may be deposited to a predetermined thickness using any desired deposition technique, such as chemical vapor deposition (CVD), plasma-enhanced chemical vapor deposition (PECVD), physical vapor deposition (PVD), atomic layer deposition (ALD), molecular beam deposition (MBD), or any combination(s) of the above. Using any desired deposition technique and target thickness(es), a first semiconductor layer 306 is deposited on the first insulating layer 304, followed in sequence by the deposition of the second insulating layer 308 (shown in plan view in FIG. 10D), the second semiconductor layer 310 (shown in plan view in FIG. 10C), and the third insulating layer 312. In the memory stack the semiconductor layers 306, 310 that will be used to form the stacked strings are vertically isolated from one another and the substrate 301 by the insulating layers 304, 308, 312.

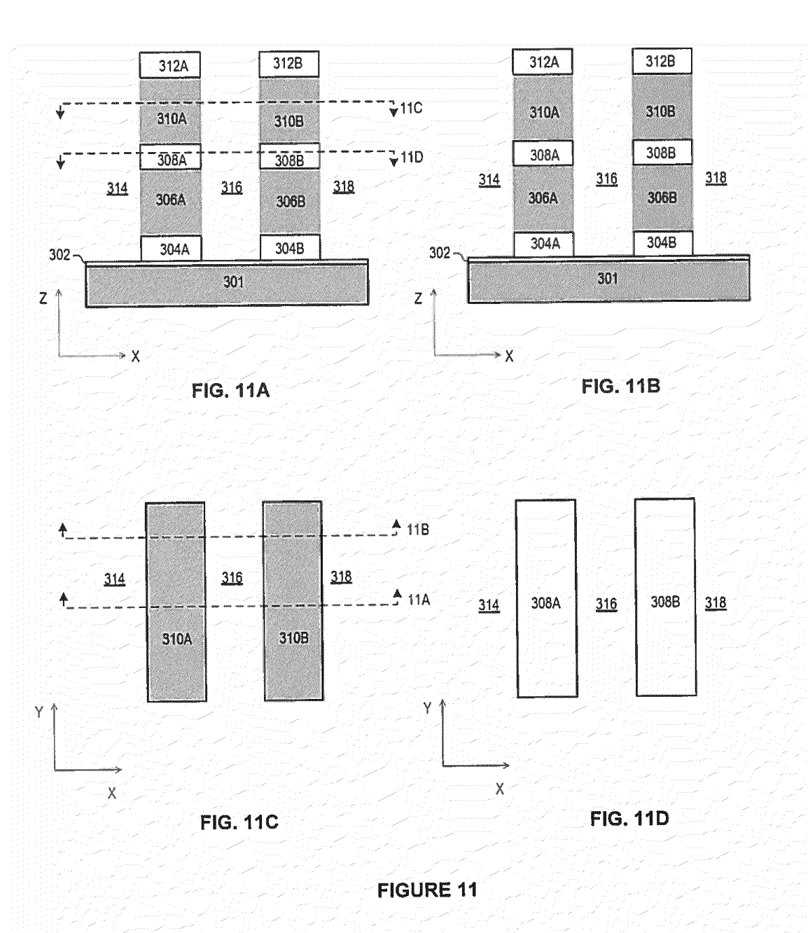

Turning now to FIG. 11, there are shown partial cross section views of the memory stack at a word line location (FIG. 11A) and an adjacent dielectric fin location (FIG. 11B), along with partial plan views through a string layer location (FIG. 11C) and adjacent isolation layer between string layers (FIG. 11D) after the memory stack is patterned and etched to form stacked strings. As shown in FIGS. 11A-B, the memory stack is patterned and etched to form openings 314-316 which define elongated narrow fin-shaped string stacks 317, 318 on the unpatterned protective layer 302. As will be appreciated, the string stacks 317, 318 may be formed using any desired technique, such as selectively etching openings 314-316 in the memory stack using a patterned mask or photoresist layer (not shown) and applying one or more anisotropic etch processes, such as an RIE etch, to define patterned openings 314-316 to form the fin-shaped string stacks 317, 318. As a result of the etch process(es), each string stack 317, 318 is formed with vertically stacked semiconductor strips 306A/B and 310A/B (shown in plan view in FIG. 11C) which are isolated from one another by the interlayer dielectric strips 308A/B (shown in plan view in FIG. 11D), 304A/B, and 312A/B.

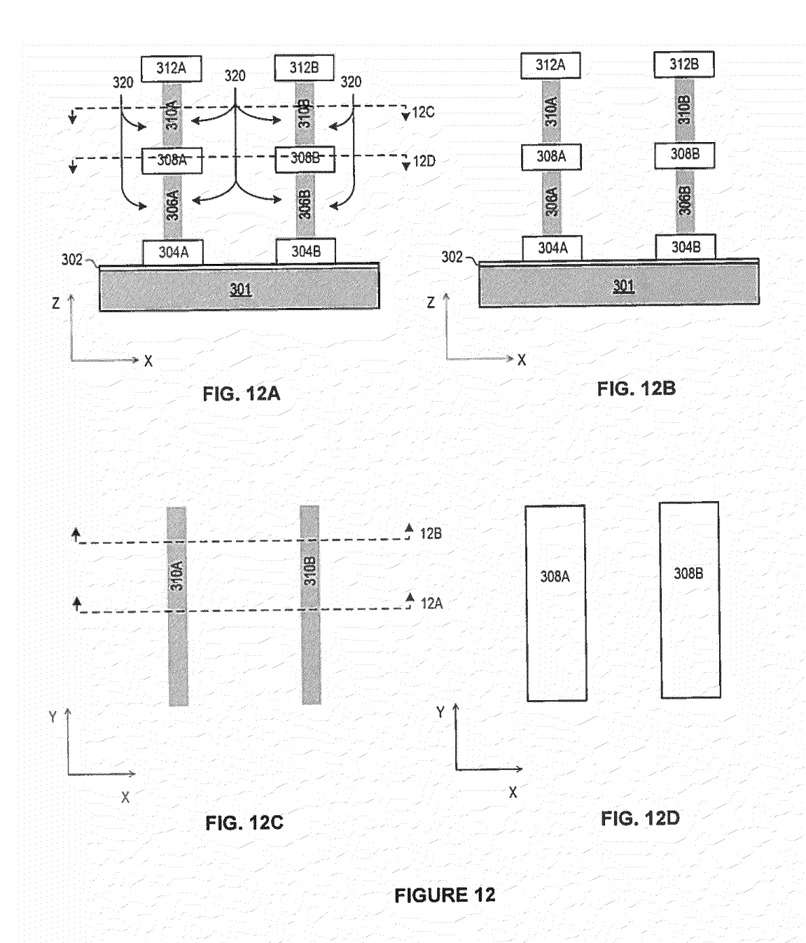

Turning now to FIG. 12, there are shown partial cross section views of the string stacks at a word line location (FIG. 12A) and an adjacent dielectric fin location (FIG. 12B), along with partial plan views through a string layer location (FIG. 12C) and adjacent isolation layer between string layers (FIG. 12D) after recess etching of the stacked strings. As shown in FIGS. 12A-B, the sidewalls of the vertically stacked strings 306A/B, 310A/B are laterally recessed relative to the sidewalls of the dielectric strips 304A/B, 308A/B, 312A/B to define recessed openings 320. As will be appreciated, any desired selective isotropic etch process may be applied to recess the string sidewalls. For example, a wet chemical etch may be applied that selectively etches and recesses the sidewalls of the semiconductor strips 306A/B, 310A/B (shown in plan view in FIG. 12C) while leaving intact the dielectric insulating layers 302, 304A/B, 308A/B (shown in plan view in FIG. 12D), 312A/B.

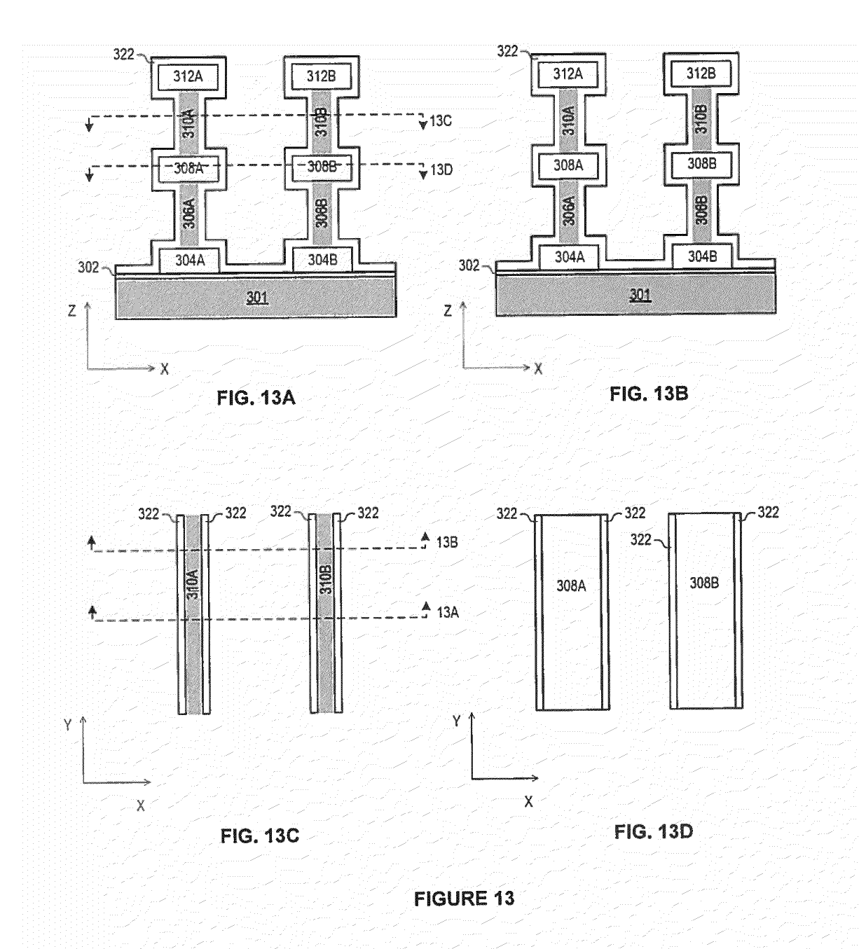

Turning now to FIG. 13, there are shown partial cross section views of the recessed string stacks at a word line location (FIG. 13A) and an adjacent dielectric fin location (FIG. 13B), along with partial plan views through a string layer location (FIG. 13C) and adjacent isolation layer between string layers (FIG. 13D) after a tunnel dielectric layer 322 is formed to cover the recessed string stacks. As shown in FIGS. 13A-B, the tunnel dielectric layer 322 may be deposited as a conformal insulating layer using any desired deposition technique, such as CVD, PECVD, PVD, ALD, MBD, or any combination(s) of the above to form a thin continuous tunnel dielectric layer covering over all of the structures fabricated in previous steps. As formed, the conformal tunnel dielectric layer 322 covers recessed string stack sidewalls in the recessed openings 320 (shown in plan view in FIG. 13C) as well as the protruding dielectric strip sidewalls (e.g., 308A) (shown in plan view in FIG. 13D).

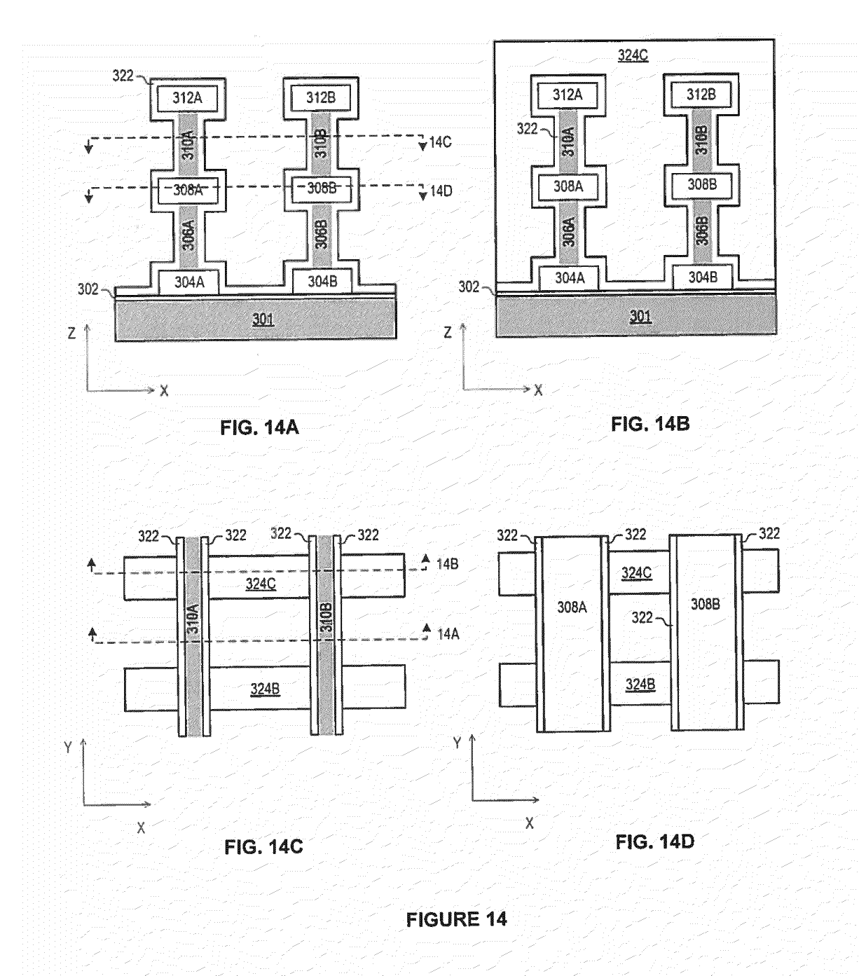

Turning now to FIG. 14, there are shown partial cross section views of the string stacks at a word line location (FIG. 14A) and an adjacent dielectric fin location (FIG. 14B), along with partial plan views through a string layer location (FIG. 14C) and adjacent isolation layer between string layers (FIG. 14D) after forming one or more patterned fin-shaped dielectric layers 324B-C to cover the string stacks between word line locations. As shown in FIGS. 14A-B, a fin-shaped dielectric line 324C may be selectively formed by depositing one or more dielectric layers (e.g., silicon oxide) over the wafer substrate, patterning the deposited dielectric layer(s) using a patterned mask or photoresist layer (not shown), and applying one or more directional etch processes, such as an RIE etch, to define patterned openings 323 over the word line locations, thereby forming the fin-shaped string stacks 324B-C between word line locations (as shown in plan view in FIGS. 14C-D). As a result, the portions of the stacked strings 306A/B, 310A/B extending between word line locations are completely surrounded and isolated by the adjacent fin-shaped dielectric layers 324B-C, thereby precluding the formation of floating gate structures in the recessed openings at these locations.

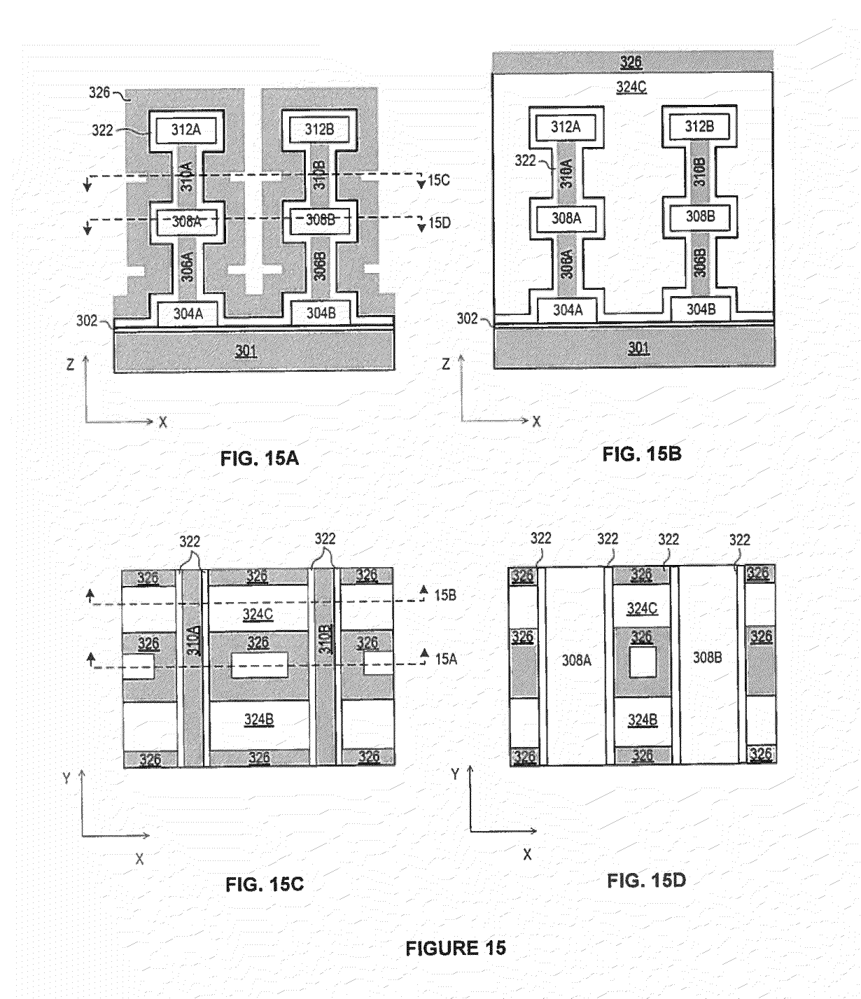

Turning now to FIG. 15, there are shown partial cross section views of the string stacks at a word line location (FIG. 15A) and an adjacent dielectric fin location (FIG. 15B), along with partial plan views through a string layer location (FIG. 15C) and adjacent isolation layer between string layers (FIG. 15D) after forming one or more conductive layers 326 to conformally cover the recessed openings in the string stacks along word line locations. As shown in FIG. 15A, the conductive layer 326 may be deposited as a conformal polysilicon layer using any desired deposition technique, such as CVD, PECVD, PVD, ALD, MBD, or any combination(s) of the above. Along the word line locations (shown in FIG. 15A), the conformal conductive layer 326 is formed on the tunneling dielectric 322 to substantially fill the recessed openings in the recessed string stack (shown in plan view in FIG. 15C) and to cover the protruding dielectric strip sidewalls (e.g., 308A/B) (shown in plan view in FIG. 15D). However, outside of the word line locations, the conductive layer 326 is formed over the previously formed fin-shaped dielectric layers 324B-C (as shown in FIG. 15B) which prevents the conductive layer 326 from being formed in the recessed openings in the string stacks outside of the word line locations (as shown in the plan view of FIGS. 15D).

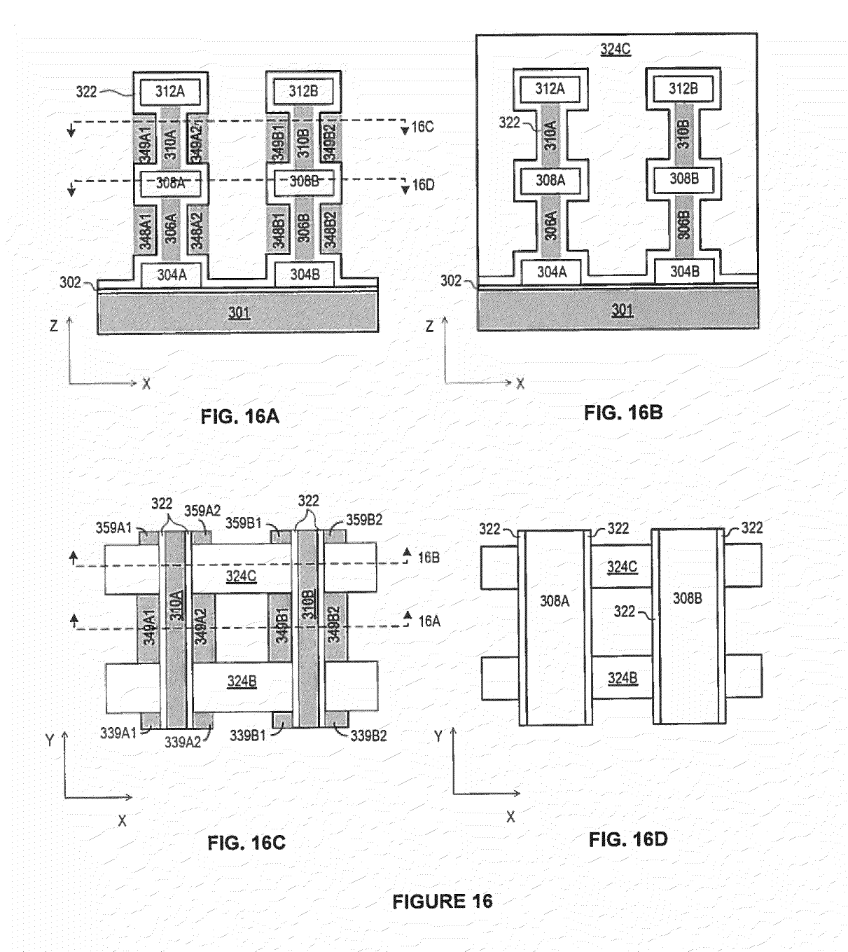

Turning now to FIG. 16, there are shown partial cross section views of the string stacks at a word line location (FIG. 16A) and an adjacent dielectric fin location (FIG. 16B), along with partial plan views through a string layer location (FIG. 16C) and adjacent isolation layer between string layers (FIG. 16D) after the conductive layer 326 is etched to form isolated floating gate nodes 348A1/A2, 348B1/B2, 349A1/A2, 349B1/B2 in the recessed openings in the string stacks along word line locations. While any etch process may be used, in selected embodiments, a directional or anisotropic etch, such as an RIE etch, may be applied to selectively remove the conductive layer 326 at all locations except for the recessed sidewall parts of the string stacks where it is protected from the etching by the protruded portions of the string stacks (e.g., 312A/B, 308A/B), thereby forming the isolated floating gate nodes 348A1/A2, 348B1/B2, 349A1/A2, 349B1/B2. However, since the sidewalls of the fin-shaped dielectric layers 324B, 324C do not have any recessed openings, the conductive material 326 is entirely removed without residue from the sidewalls of the fin-shaped dielectric layers 324B, 324C. In other embodiments, the selective removal of the conductive layer 326 may use a patterned mask or photoresist layer to control the etch process. The directional etch process may be supplemented by a subsequent isotropic (e.g., wet) etch process to ensure that any residues are removed. However formed, the floating gate nodes 348A1/A2, 348B1/B2, 349A1/A2, 349B1/B2 are isolated from one another in the vertical direction by the interlayer dielectric layers 304A/B, 308A/B, 312A/B, 322 (as shown in FIGS. 16A and 16D). In addition, the floating gate nodes (e.g., 349A1/A2, 349B1/B2) are isolated from other floating gates in the lateral direction (e.g., 339A1/A2, 339B1/B2, 359A1/A2, 359B1/B2) by the fin-shaped dielectric layers (e.g., 324B, 324C) as shown in the plan view of FIGS. 16C. As a result of selectively removing the conductive layer 326, the isolated floating gate nodes 348A1/A2, 348B1/B2, 349A1/A2, 349B1/B2 are fabricated adjacent to the strings, and are isolated from neighboring floating gates in the z-direction as well as the x and y-directions.

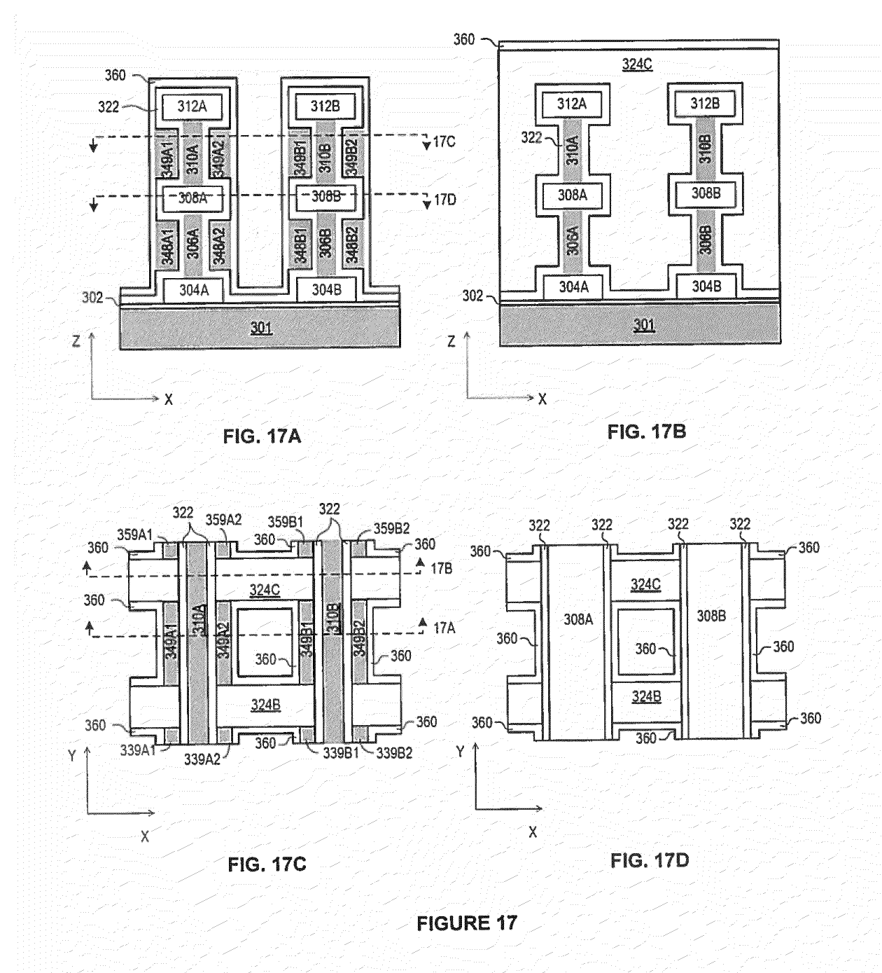

Turning now to FIG. 17, there are shown partial cross section views of the string stacks at a word line location (FIG. 17A) and an adjacent dielectric fin location (FIG. 17B), along with partial plan views through a string layer location (FIG. 17C) and adjacent isolation layer between string layers (FIG. 17D) after a coupling dielectric layer 360 is formed to cover the stacked strings and fin-shaped dielectric layers. As shown in FIGS. 17A-B, the coupling dielectric layer 360 may be deposited as a conformal insulating layer using any desired deposition or growth technique, such as thermal oxidation, CVD, PECVD, PVD, ALD, MBD, or any combination(s) of the above to form a thin continuous coupling dielectric layer that covers at least the exposed sidewalls of the floating gate nodes 348A1/A2, 348B1/B2, 349A1/A2, 349B1/B2 (as shown in FIGS. 17A and 17C) as well as the top and sidewall surfaces of the fin-shaped dielectric layers 324B, 324C (shown in FIGS. 17B and 17D).

Referring back to FIGS. 6-9, the final structure of the vertical gate NAND flash memory structure is shown after the select gate structures (e.g., word line, string select line, or ground select line structures) are fabricated. For example, the cross-sectional view of FIG. 6 shows a word line gate structure 364 may be selectively formed with one or more doped semiconductor gate layers (e.g., silicided n-type polysilicon) to completely cover the plurality of string stacks so that the semiconductor gate layer(s) 364 form a continuous conductive line along the word line direction. And as shown with the plan view of FIG. 8, the select gate structures may be formed as self-aligned gate structures by depositing one or more conductive gate layers 363-367 to fill the openings between the fin-shaped dielectric layers 324B, 324C and cover the stacked string structures. A subsequent etch back or chemical-mechanical polishing step may then be applied to planarize the conductive gate layers 363-367 down to the fin-shaped dielectric layers 324B, 324C without exposing the top of the stacked string structures, thereby ensuring that adjacent word lines (e.g., 364, 365) are separated from each other by an isolating fin-shaped dielectric structure (e.g., 324C) in a self-aligned process.

As disclosed herein, the formation of isolated charge trap nodes, such as floating gates or other charge trap devices, in a vertically stacked NAND flash memory device, is efficiently provided with a manufacturing process which forms alternating recessed sidewall structures of the string stacks and the patterned fin-shaped dielectric layers with uniform sidewall structures prior to formation of the charge trap devices in the recessed sidewall structures. By forming the patterned fin-shaped dielectric layers around the string stacks between word line locations prior to deposition and etching of floating gate material, the floating gate material is not deposited around the string stacks in adjacent regions between word line locations because they are masked by the patterned fin-shaped dielectric layers, thereby providing floating gate node isolation in the horizontal (e.g., y-direction) direction. Due to the combined effect of recessed sidewall structure of the string stacks running in the y-direction on the one hand and the dielectric fin pattern with uniform sidewall structure running in the x-direction on the other hand, it is ensured that simultaneous node isolation in the y-direction and z-direction occurs at the step where the floating gate material is etched.

By now it should be appreciated that there is provided herein a three-dimensional integrated circuit non-volatile memory device with charge storage node isolation. The disclosed memory device includes a plurality of string stacks laterally disposed over a substrate to extend in parallel over the surface of the substrate and to intersect with a plurality of parallel conductive gate structures separated from one another by intervening fin-shaped dielectric structures. In selected embodiments, each string stack may be a plurality of vertically stacked NAND memory cell strings, each NAND memory cell string comprising a plurality of transistors which are connected in series between a bit line contact and a source line contact. In other embodiments, each string stack is formed with conductive strips and insulating strips vertically stacked alternately together with the conductive strips separated from each other by the insulating strips. In addition, a charge storage node is positioned between each conductive strip and each intersecting conductive gate structure, where each charge storage node is isolated from neighboring charge storage nodes in two perpendicular lateral directions and a vertical direction. As formed, each charge storage node is separated from the conductive strip by a first tunneling dielectric layer and is separated from the intersecting conductive gate structure by a second coupling dielectric layer. In selected embodiments, each charge storage node is confined in recessed sidewall portions of the string stacks. In addition, each charge storage node may be implemented as a floating gate that is positioned between a conductive strip and a first intersecting conductive gate structure that is isolated by an adjacent fin-shaped dielectric structure from a neighboring charge storage node positioned between said conductive strip and a second intersecting conductive gate structure located on an opposite side of the adjacent fin-shaped dielectric structure. To provide such isolation, the floating gates are formed around the string stacks after the intervening fin-shaped dielectric structures are formed around the string stacks. As a result, each floating gate may be formed as a self-aligned floating gate that is isolated from neighboring floating gates in x, y and z directions.

In another form, there is provided a semiconductor device and method for forming same. In the disclosed methodology, a plurality of string stacks are formed to extend in parallel over a substrate, where each string stack includes vertically stacked semiconductor layers having recessed sidewalls that are isolated from one another by interlevel dielectric layers. In selected embodiments, the string stacks may be formed by selectively etching a memory stack having semiconductor layers formed over a substrate and isolated from one another by isolating interlevel dielectric layers, such as by forming a patterned etch mask over the memory stack to define etch openings and applying one or more anisotropic etch processes with the patterned etch mask in place to selectively remove portions of the memory stack under the etch openings, thereby forming a plurality of vertically stacked patterned semiconductor layers and interlevel dielectric layers having substantially coplanar sidewalls. To recess the sidewalls of the plurality of vertically stacked semiconductor layers relative to the sidewalls of the patterned interlevel dielectric layers, one or more isotropic etch processes may also be applied. On the string stacks, a first dielectric layer is formed to conformally coat the string stacks while leaving a recess opening adjacent to the recessed sidewalls of the vertically stacked semiconductor layers. For example, the first dielectric layer may be deposited as a conformal silicon oxide layer to form a thin continuous tunnel dielectric layer covering the recessed sidewalls of the vertically stacked semiconductor layers as well as protruding sidewalls of the interlevel dielectric layers. In addition, a plurality of dielectric structures are formed to define a word line openings extending in a word line direction and to cover the string stacks outside of the word line openings. In selected embodiments, the dielectric structures may be formed by depositing one or more dielectric layers to completely cover the string stacks and the first dielectric layer, forming a patterned etch mask over the one or more dielectric layers to define etch openings, and applying one or more anisotropic etch processes with the patterned etch mask in place to selectively remove portions of one or more dielectric layers under the etch openings, thereby forming the plurality of dielectric structures to define the word line openings extending in the word line direction. In each of the word line openings, charge storage nodes are selectively formed to fit within each recess opening adjacent to the recessed sidewalls of the vertically stacked semiconductor layers. In selected embodiments, the charge storage nodes may be formed by depositing one or more conductive layers in the word line openings to cover the string stacks and first dielectric layer formed therein, thereby filling each recess opening adjacent to the recessed sidewalls of the vertically stacked semiconductor layers. After depositing the conductive layer(s), one or more anisotropic etch processes are applied to remove the conductive layer(s) except for any portions thereof located in the recess openings, thereby forming a charge storage node to fit within each recess opening adjacent to the recessed sidewalls of the vertically stacked semiconductor layers. In other embodiments, the charge storage nodes may be formed by depositing one or more conductive polysilicon layers in the word line openings to conformally coat the string stacks and first dielectric layer formed therein, thereby filling each recess opening adjacent to the recessed sidewalls of the vertically stacked semiconductor layers, where the plurality of dielectric structures prevents the one or more conductive polysilicon layers from conformally coating the plurality of string stacks and first dielectric layer covered by the plurality of dielectric structures. After depositing the conductive polysilicon layer(s), one or anisotropic etch processes are applied using protruding sidewalls of the interlevel dielectric layers as a self-aligned etch mask to remove the conductive polysilicon layer(s) except for any portions thereof located in the recess openings, thereby forming a charge storage node to fit within each recess opening adjacent to the recessed sidewalls of the vertically stacked semiconductor layers. After forming the charge storage nodes, a second dielectric layer is formed to conformally coat the string stacks and any exposed charge storage node surface in the word line openings. For example, the second dielectric layer may be deposited as a conformal silicon oxide layer to form a thin continuous coupling dielectric layer covering the string stacks and any exposed charge storage node surface in the word line openings. On the second dielectric layer, a conductive word line structure is formed in each of the word line openings to surround the string stacks and each charge storage node, where each charge storage node is isolated from neighboring charge storage nodes in two perpendicular lateral directions and a vertical direction. In selected embodiments, the conductive word line structure may be formed by depositing one or more conductive polysilicon layers to completely fill the plurality of word line openings and to cover the plurality of dielectric structures, and then planarizing the conductive polysilicon layer(s) with an etch or polish step until substantially coplanar with the plurality of dielectric structures, thereby forming a conductive word line structure in each of the plurality of word line openings. In selected embodiments, each charge storage node is formed as a floating gate that is separated from an adjacent recessed sidewall of stacked semiconductor layer by the first dielectric layer and is separated from the surrounding conductive word line structure by the second dielectric layer. In this way, each floating gate is formed as a self-aligned floating gate that is isolated from neighboring floating gate in x, y and z directions.

In yet another form, there is provided a semiconductor device and method for forming same. In the disclosed methodology, a plurality of string stacks is formed to extend in a bit line direction over a substrate. As formed, each string stack includes alternating layers of vertically stacked semiconductor strips and dielectric strips with a topmost dielectric strip, where the semiconducting strips have sidewalls which are recessed in a word line direction relative to sidewalls of the dielectric strips to define a recessed profile adjacent to each semiconductor strip. On the string stacks, a tunnel dielectric layer is formed to conformally cover the string stacks without filling the recessed profiles. In addition, a plurality of separate dielectric fin structures extending in a word line direction are patterned over the plurality of string stacks to define a plurality of word line openings which expose the plurality of string stacks and tunnel dielectric layer inside the plurality of word line openings and to cover the plurality of string stacks and tunnel dielectric layer outside of the plurality of word line openings. In the word line openings, a conductive polysilicon layer may be deposited to cover the plurality of separate dielectric fin structures and the plurality of string stacks, thereby filling the recessed profiles. By etching the conductive polysilicon layer, charge storage nodes are formed in the recessed profiles that are isolated from charge storage nodes in laterally adjacent string stacks by one or more of the separate dielectric fin structures. In selected embodiments, the conductive polysilicon layer is etched with a directional etch of the conductive polysilicon layer to form floating gates that are isolated vertically and in the word line direction by using the topmost dielectric strip and the plurality of separate dielectric fin structures as an etch mask to protect the conductive polysilicon layer formed in the recessed profiles of the plurality of string stacks, but to otherwise remove the conductive polysilicon layer, thereby forming the floating gates in the recessed profiles of the plurality of string stacks.

Although the described exemplary embodiments disclosed herein are directed to various nonvolatile memory device structures and methods for making and operating same by providing interleaved NAND string stacks having charge trap nodes that are isolated in both lateral and vertical directions, the present invention is not necessarily limited to the example embodiments which illustrate inventive aspects of the present invention that are applicable to a wide variety of fabrication processes and/or structures. Thus, the particular embodiments disclosed above are illustrative only and should not be taken as limitations upon the present invention, as the invention may be modified and practiced in different but equivalent manners apparent to those skilled in the art having the benefit of the teachings herein. For example, while the NAND cell transistors are described as n-channel transistors on p-type (or undoped) substrate, this is merely for illustration purposes, and it will be appreciated that n and p-type impurities may be interchanged so as to form p-channel transistors on n-type substrate, or the substrate may consist of undoped silicon. In addition, the flash memory cells are illustrated herein as being embodied as vertical gate NAND memory cell strings, but this is merely for convenience of explanation and not intended to be limiting and persons of skill in the art will understand that the principles taught herein apply to other suitable kinds of cell structures and the resulting different bias conditions. It will also be appreciated that the disclosed technique for providing an isolated charge trap node is not tied to any specific cell technology. For example, the disclosed techniques for isolating floating gate devices may also be used to form isolated charge trap devices or any other type of isolated charge storage nodes, even in the case of charge trapping devices such as SONOS. Moreover, the figures illustrate examples in which there are two or three stacked layers of strings, but other embodiments are not restricted to any specific number of layers, and even work for single layer cell arrays. In addition, the terms of relative position used in the description and the claims, if any, are interchangeable under appropriate circumstances such that embodiments of the invention described herein are, for example, capable of operation in other orientations than those illustrated or otherwise described herein. The term “coupled,” as used herein, is defined as directly or indirectly connected in an electrical or non-electrical manner. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” “includes,” “including,” “has,” “having,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A vertical gate NAND memory device, comprising:
a substrate having an upper surface;
a plurality of string stacks laterally disposed over the substrate to extend in parallel over the surface of the substrate and to intersect with a plurality of parallel conductive gate structures separated from one another by intervening fin-shaped dielectric structures, where each string stack comprises conductive strips and insulating strips vertically stacked alternately with the conductive strips separated from each other by the insulating strips; and
a charge storage node positioned between each conductive strip and each intersecting conductive gate structure, where each charge storage node is isolated from neighboring charge storage nodes in two perpendicular lateral directions and a vertical direction.

2. The vertical gate NAND memory device of claim 1, where each charge storage node is separated from the conductive strip by a first tunneling dielectric layer and is separated from the intersecting conductive gate structure by a second coupling dielectric layer.

3. The vertical gate NAND memory device of claim 1, where each charge storage node is confined in recessed sidewall portions of the string stacks.

4. The vertical gate NAND memory device in claim 3, where each charge storage node positioned between each conductive strip and a first intersecting conductive gate structure is isolated by an adjacent fin-shaped dielectric structure from a neighboring charge storage node positioned between said conductive strip and a second intersecting conductive gate structure located on an opposite side of the adjacent fin-shaped dielectric structure.

5. The vertical gate NAND memory device of claim 4, where each charge storage node is a floating gate.

6. The vertical gate NAND memory device of claim 5, where each floating gate is formed after the intervening fin-shaped dielectric structures.

7. The vertical gate NAND memory device of claim 5, where each floating gate comprises a self-aligned floating gate that is isolated from neighboring floating gate in x, y and z directions.

8. The vertical gate NAND memory device of claim 1, where each string stack comprises a plurality of vertically stacked NAND memory cell strings, each NAND memory cell string comprising a plurality of transistors which are connected in series between a bit line contact and a source line contact.

9. A method for forming a semiconductor device, comprising:
forming a plurality of string stacks extending in parallel over a substrate, each string stack comprising a plurality of vertically stacked semiconductor layers having recessed sidewalls that are isolated from one another by interlevel dielectric layers;
forming a first dielectric layer to conformally coat the plurality of string stacks while leaving a recess opening adjacent to the recessed sidewalls of the plurality of vertically stacked semiconductor layers;
forming a plurality of dielectric structures to define a plurality of word line openings extending in a word line direction and to cover the plurality of string stacks outside of the plurality of word line openings;
selectively forming in each of the plurality of word line openings a charge storage node to fit within each recess opening adjacent to the recessed sidewalls of the plurality of vertically stacked semiconductor layers;
forming a second dielectric layer to conformally coat the plurality of string stacks and any exposed charge storage node surface in the plurality of word line openings;
forming a conductive word line structure in each of the plurality of word line openings and on the second dielectric layer to surround the plurality of string stacks and each charge storage node, where each charge storage node is isolated from neighboring charge storage nodes in two perpendicular lateral directions and a vertical direction.

10. The method of claim 9, where forming the plurality of string stacks comprises:
forming a memory stack over a substrate comprising a plurality of semiconductor layers isolated from one another by isolating interlevel dielectric layers;
forming a patterned etch mask over the memory stack to define etch openings over the memory stack;
applying one or more anisotropic etch processes with the patterned etch mask in place to selectively remove portions of the memory stack under the etch openings, thereby forming a plurality of vertically stacked patterned semiconductor layers and interlevel dielectric layers having substantially coplanar sidewalls; and
applying one or more isotropic etch processes to recess the sidewalls of the plurality of vertically stacked semiconductor layers relative to the sidewalls of the patterned interlevel dielectric layers.

11. The method of claim 9, where forming the first dielectric layer comprises depositing as a conformal silicon oxide layer to form a thin continuous tunnel dielectric layer covering the recessed sidewalls of the vertically stacked semiconductor layers as well as protruding sidewalls of the interlevel dielectric layers.

12. The method of claim 9, where forming the plurality of dielectric structures comprises:
depositing one or more dielectric layers to completely cover the plurality of string stacks and the first dielectric layer;
forming a patterned etch mask over the one or more dielectric layers to define etch openings;
applying one or more anisotropic etch processes with the patterned etch mask in place to selectively remove portions of one or more dielectric layers under the etch openings, thereby forming the plurality of dielectric structures to define the plurality of word line openings extending in the word line direction.

13. The method of claim 9, where selectively forming in each of the plurality of word line openings a charge storage node comprises:
depositing one or more conductive layers in the plurality of word line openings to cover the plurality of string stacks and first dielectric layer formed therein, thereby filling each recess opening adjacent to the recessed sidewalls of the plurality of vertically stacked semiconductor layers; and
applying one or more anisotropic etch processes to remove the one or more conductive layers except for any portions thereof located in the recess openings, thereby forming a charge storage node to fit within each recess opening adjacent to the recessed sidewalls of the plurality of vertically stacked semiconductor layers.

14. The method of claim 9, where selectively forming in each of the plurality of word line openings a charge storage node comprises:
depositing one or more conductive polysilicon layers in the plurality of word line openings to conformally coat the plurality of string stacks and first dielectric layer formed therein, thereby filling each recess opening adjacent to the recessed sidewalls of the plurality of vertically stacked semiconductor layers, where the plurality of dielectric structures prevents the one or more conductive polysilicon layers from conformally coating the plurality of string stacks and first dielectric layer covered by the plurality of dielectric structures; and
applying one or more anisotropic etch processes using protruding sidewalls of the interlevel dielectric layers as a self-aligned etch mask to remove the one or more conductive layers except for any portions thereof located in the recess openings, thereby forming a charge storage node to fit within each recess opening adjacent to the recessed sidewalls of the plurality of vertically stacked semiconductor layers.

15. The method of claim 9, where forming the second dielectric layer comprises depositing as a conformal silicon oxide layer to form a thin continuous coupling dielectric layer covering the plurality of string stacks and any exposed charge storage node surface in the plurality of word line openings.

16. The method of claim 9, where forming the conductive word line structure comprises:
depositing one or more conductive polysilicon layers to completely fill the plurality of word line openings and to cover the plurality of dielectric structures;
planarizing the one or more conductive polysilicon layers until substantially coplanar with the plurality of dielectric structures, thereby forming a conductive word line structure in each of the plurality of word line openings.

17. The method of claim 9, where each charge storage node is formed as a floating gate that is separated from an adjacent recessed sidewall of stacked semiconductor layer by the first dielectric layer and is separated from the surrounding conductive word line structure by the second dielectric layer.

18. The method of claim 17, where each floating gate comprises a self-aligned floating gate that is isolated from neighboring floating gate in x, y and z directions.

19. A method, comprising:
forming a plurality of string stacks to extend in a bit line direction over a substrate, each string stack comprising alternating layers of vertically stacked semiconductor strips and dielectric strips with a topmost dielectric strip, where the semiconducting strips have sidewalls which are recessed in a word line direction relative to sidewalls of the dielectric strips to define a recessed profile adjacent to each semiconductor strip;
forming a tunnel dielectric layer to conformally cover the plurality of string stacks without filling the recessed profiles;
patterning a plurality of separate dielectric fin structures extending in a word line direction over the plurality of string stacks to define a plurality of word line openings which expose the plurality of string stacks and tunnel dielectric layer inside the plurality of word line openings and to cover the plurality of string stacks and tunnel dielectric layer outside of the plurality of word line openings;
depositing a conductive polysilicon layer to cover the plurality of separate dielectric fin structures and the plurality of string stacks, thereby filling the recessed profiles; and
etching the conductive polysilicon layer to form charge storage nodes in the recessed profiles that are isolated from charge storage nodes in laterally adjacent string stacks by one or more of the separate dielectric fin structures.

20. The method of claim 19, where etching the conductive polysilicon layer comprises directionally etching the conductive polysilicon layer to form floating gates that are isolated vertically and in the word line direction by using the topmost dielectric strip and the plurality of separate dielectric fin structures as an etch mask to protect the conductive polysilicon layer formed in the recessed profiles of the plurality of string stacks, but to otherwise remove the conductive polysilicon layer, thereby forming the floating gates in the recessed profiles of the plurality of string stacks.
